(19) United States
(12) Patent Application Publication
(10) Pub. No.: US 2023/0133484 A1
(43) Pub. Date: May 4, 2023

(54) INTERCONNECTS WITH LINER THAT RESONATES DURING MICROWAVE ANNEAL

(71) Applicant: Intel Corporation, Santa Clara, CA (US)

(72) Inventors: Prashant Majhi, San Jose, CA (US); Anand Murthy, Portland, OR (US)

(73) Assignee: Intel Corporation, Santa Clara, CA (US)

(21) Appl. No.: 17/452,803

(22) Filed: Oct. 29, 2021

(51) Int. Cl. H01L 21/768; H01L 23/522; H01L 23/532

(52) U.S. Cl. CPC H01L 21/76882; H01L 23/5226; H01L 23/53238; H01L 23/53223; H01L 23/53266; H01L 23/53295; H01L 21/76864; H01L 21/76846; H01L 21/76843

(57) ABSTRACT

An integrated circuit has a first layer having a recess that extends into the first layer. In addition, a second layer is within the recess and comprises a metal or a dielectric, and a third layer is within the recess and between the first and second layers, the third layer including a material that resonates at microwave frequencies (e.g., 2.4 GHz to 2.5 GHz). In some cases, the third layer material includes: (1) oxygen along with indium and/or zinc; or (2) diethylene glycol dibenzoate. In some cases, such as where the first layer comprises a dielectric (e.g., silicon dioxide) and second layer comprises a metal (e.g., copper), the integrated circuit further includes a fourth layer (e.g., barrier layer including tantalum or titanium) between the second and third layers. The third layer resonates in response to microwave annealing, thereby selectively heating the second layer (e.g., to reflow and/or grow grain size).

### FIELD OF THE DISCLOSURE

The present disclosure relates to integrated circuits, and more particularly, to interconnects.

### BACKGROUND

As integrated circuit scaling continues, it is becoming increasingly difficult to scale interconnects to simultaneously satisfy interconnect density and resistance needs. In particular, while interconnect metal line widths (in the x-plane) shrink to support line density, the line heights (in the y-plane) do not shrink as much. This maintaining of line height helps dampen the significant increase in line resistance caused by the line width scaling. Such increased line resistance is due to electron scattering from roughness, and grain boundary, as well as limited grain size. However, the high aspect ratio (height-to-width) of the metal lines involves filling high aspect ratio interconnect features, whether it be filling recesses with conductive material to form the metal lines themselves or filling recesses with dielectric material to form dielectric structures between to metal lines. In any such cases, the higher the height-to-width aspect ratio of the trench to be filled, the more difficult to successfully fill that trench. To this end, there are a number of non-trivial issues associated with scaling interconnects.

### BRIEF DESCRIPTION OF THE DRAWINGS

FIGS. 1a-b each illustrates a cross-section view of an example an example interconnect structure of an integrated circuit, configured with a liner that allows for selective annealing of interconnect fill material, in accordance with an embodiment of the present disclosure.

FIGS. 2a-b each illustrates a cross-section view of another example interconnect structure of an integrated circuit configured with a liner that allows for selective annealing of interconnect fill material, in accordance with an embodiment of the present disclosure.

FIG. 2c schematically illustrates a cross-section view of an example integrated circuit having a device layer and an interconnect structure, the interconnect structure configured with a liner that allows for selective annealing of interconnect fill material, in accordance with still other embodiments of the present disclosure.

FIGS. 3a-d collectively illustrate cross-section views that demonstrate a methodology for selective annealing to provide better gap fill of interconnect fill material, in accordance with an embodiment of the present disclosure.

FIGS. 4a-d collectively illustrate cross-section views that demonstrate a methodology for selective annealing to provide increased grain size in interconnect fill material, in accordance with an embodiment of the present disclosure.

FIG. 5 illustrates a methodology for selective microwave-based annealing of interconnect fill material, in accordance with an embodiment of the present disclosure.

FIG. 6 illustrates a computing system implemented with one or more integrated circuit structures configured in accordance with an embodiment of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, tapered sidewalls, rounded corners, and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

An integrated circuit structure has a first layer having a recess that extends into the first layer. A second layer is within the recess and comprises a metal or a dielectric. A third layer is within the recess and between the first and second layers, the third layer including a material that resonates at microwave frequencies (e.g., 2.4 to 2.5 Gigahertz). In some cases, for example, the third layer material includes: (1) oxygen along with indium and/or zinc (e.g., indium tin oxide; indium gallium zinc oxide; indium tungsten oxide; or zinc oxide); or (2) diethylene glycol dibenzoate. In some example cases, such as where the first layer comprises a dielectric (e.g., silicon dioxide or other interlayer dielectric) and second layer comprises a metal (e.g., copper), the integrated circuit may further include a relatively thin fourth layer (e.g., barrier layer including tantalum or titanium) between the second and third layers. The third layer resonates in response to microwave annealing and allows for selective reflow and/or grain growth of the second layer. In particular, the third layer heats the second layer (and any barrier layer, if present). For metals, the thermal conduction is relatively high and hence the third layer readily heats the metal volume of the second layer; for dielectrics, the thermal conduction is lower, but the heat generated by the third layer can still cause some reflow of dielectric volume of the second layer in relatively narrow width trenches (e.g., for better gap fill in high aspect ratio trenches). Previously provisioned layers of the integrated circuit (e.g., the device layer or other layers not in contact with the third layer) do not resonant at microwave frequency range and hence there is no source to absorb microwave energy and heat-up. Numerous embodiments and variations will be appreciated in light of this disclosure.

### General Overview

As previously noted above, the aspect ratio of interconnect metal lines increases so does the aspect ratio of interconnect features to be filled with dielectric or metal, and filling such high aspect ratio interconnect features can be problematic. For instance, when filling such high aspect ratio trenches, pinch-off can occur at the opening of the trench being filled, which in turn prevents the lower portion of that trench from being filled (poor gap fill). One option to address this poor gap fill is to heat the deposited material by an anneal process to reflow and/or increase grain size of the deposited material. However, such an option may not be appropriate for all applications. For example, flash and laser anneal are suitable to cause an increase in grain size and reflow of the deposited material, but they are not selective anneals in that they also affect other layers in addition to the target layer. Thus, such anneals cannot be used extensively without causing damage to the integrity of the underlying or otherwise previously deposited layers. To this end, for example, the thermal budget for backend or otherwise subsequent interconnect formation is limited due to thermal sensitivity of the previously formed device layer, which includes sensitive materials and componentry such as high-k dielectrics and transistor junctions. Shorter duration anneals (e.g., micro-second and nano-second anneals) may cause less collateral damage, but the thermal energy from such short anneals is limited and thus may not be able to induce sufficient reflow and/or grain growth. Another possible option for better gap fill is to use a more complex deposition process, such as a relatively slow atomic layer deposition (ALD) process, or an iterative deposit-etch-deposit process. Such processes, however, can be relatively expensive and moreover may not be successful without an anneal-based reflow, particularly when forming interconnect features in high aspect ratio trenches.

Thus, techniques are disclosed for providing highly scalable interconnects. Although the techniques can be used in any interconnect processes, they are particularly useful in backend interconnects having high aspect ratio features. In an example, a thin conformal film (liner) is deposited on the sidewalls of a trench to be filled, and a conductive fill material is deposited into the trench on the liner. In other such examples, there may be a barrier layer between the liner and the conductive fill material (e.g., to inhibit electromigration of copper into surrounding dielectric material). In any such cases, a microwave anneal is then conducted. The liner is configured to resonate at the microwave frequency range and thus absorbs microwave energy to selectively anneal (heat) the conductive fill material to modify its structure (grain size) and/or gap fill. In another example, the fill material is a dielectric. In such cases, the liner allows for better gap fill and densification of the dielectric material. In any such cases, the anneal is selective to the deposited fill material and other layer(s) that the liner is in contact with, and other layers (such as layers in the device layer or layers within bit cells) are not subjected to heat. This selective nature maintains the integrity of previously deposited thin films or otherwise sensitive materials and devices.

Some examples of materials that resonate at microwave frequencies (e.g., 2.4-2.5 GHz) or otherwise absorb microwave energy and can be used for the liner are (a) organic thin films like diethylene glycol dibenzoate (DEGDB), and (b) inorganic thin films like doped indium and zinc based oxides (e.g., indium tin oxide; indium gallium zinc oxide; indium tungsten oxide; or zinc oxide). Example materials that do not resonate at microwave frequencies include, for instance, silicon, silicon dioxide, titanium, titanium nitride, tantalum, and tantalum nitride; such materials thus have no source to absorb microwave energy and heat-up. The liner materials can be deposited by conformal deposition techniques like atomic layer deposition (ALD) or chemical vapor deposition (CVD). The thickness of the liner can vary from one embodiment to the next, but in some example cases is in the range of one to three monolayers to 40 angstroms, such as 5-30 angstroms.

Note that the conductivity (or resistivity, as the case may be) of the liner material can be tuned to maximize or otherwise achieve a desired level of microwave energy absorption. For example, relatively high microwave energy absorption can be achieved when the liner has a conductivity in the range of about 1000-10000 siemens per meter (S/m). In terms of resistivity, a relatively high microwave energy absorption can be achieved when the liner has a resistivity in the range of about 10⁻⁴ to 10⁻³ ohm meters (Ω·m). To this end, the conductivity (or resistivity) of the microwave absorbing liner plays a role in the microwave interaction (e.g., in terms of absorption and reflection of energy and conduction within the liner material). Further note that the liner actually heats any material with which it is in contact. The amount of heat imparted by the microwave-resonant liner into its neighboring layer(s) will depend on factors such as the surface area of the contact as well as the material being heated and the thickness or volume of that material.

So, for instance, consider the example case where the liner is deposited on the walls of a high aspect ratio recess (e.g., trench or via having a height-to-width ratio of 4:1 or higher (e.g., 5:1, 6:1, 7:1, etc.) in a relatively large volume of dielectric material (e.g., silicon dioxide), and the fill material is a metal (and possibly with a metal-containing barrier layer between the liner and the metal fill material). For such metal and metal-containing materials, the heat conduction is relatively high and hence the liner readily heats the volume of metal fill material (and any metal-containing barrier layer, if present). Example fill metals include, for instance, copper, aluminum, tungsten, molybdenum, ruthenium, or alloys of same. Example barrier materials include tantalum, titanium or nitrides of same (e.g., titanium nitride, tantalum nitride, titanium silicon nitride, tantalum silicon nitride). On the other hand, the thermal conduction for the relatively large volume of dielectric on which the liner sits is relatively poor, so that relatively large bulk of dielectric material will not be sufficiently heated so as to reflow or otherwise materially change in its structure.

Further consider the example case where the liner is deposited on the walls of a high aspect ratio recess that is similar to that above but in a relatively large volume of a metal-containing material, and the relatively smaller volume of fill material is a dielectric (and possibly with a metal-containing barrier layer between the liner and the dielectric fill material). Even though the heat conduction in dielectric fill material is relatively poor, the heat generated by the liner may be sufficient to heat the smaller volume of dielectric material within the high aspect ratio recess so as to achieve at least some reflow in that volume of dielectric material. To this end, the liner can be used to heat dielectric material in high aspect ratio narrow openings to achieve better gap fill, according to some examples. Example dielectric materials that can be reflowed include, for instance, silicon dioxide, or low-k variants such as silicon dioxide doped with carbon, hydrogen, nitrogen, or fluorine.

In any such cases, the microwave-based anneal can be carried out to selectively heat the layers in contact with the liner. In some embodiments, the range of microwave energy used during the anneal process is in the range of 2.4-2.5 Gigahertz (e.g., 2.45 GHz). The duration of the anneal can vary from one embodiment to the next, and depends on factors such as the volume to be heated and the thickness of the liner. The greater the volume and/or the thicker the liner, the longer the anneal may be. An example duration is in the range of several seconds to several minutes, although some examples may call for an even longer duration. Use of the techniques provided herein will manifest in a number of ways. For example, cross-sectional imaging of the interconnect layers by way of scanning electron microscopy or SEM, transmission electron microscopy or TEM, or other suitable inspection tool will reveal the use of a microwave absorbing liner, as variously described herein.

### Architecture

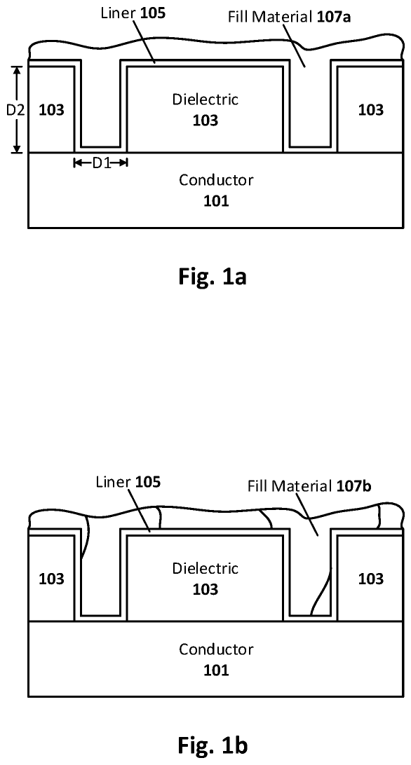

FIGS. 1a-b each illustrates a cross-section view of an example interconnect structure of an integrated circuit, configured with a liner that allows for selective annealing of interconnect fill material, in accordance with an embodiment of the present disclosure. Each of these examples generally includes two interconnect layers (sometimes call metallization layers). As can be seen in this example, the upper layer includes recesses that are fabricated in a dielectric layer 103. The recesses can be used, for example, as conductive pathways, vias, or other such metal interconnect features. A liner 105 lines the sides and bottom of each recess, and a fill material 107a or 107b fills the remaining portion of the recesses. An overflow of the deposited fill material 107a-b has not yet been removed. The lower layer includes a conductor 101 that extends under each of the recesses. Note that dielectric material of the lower layer is not visible in this particular cross-section.

As will be appreciated, other interconnect structure configurations including conductive features having any number of profiles, geometries, and functions can benefit from the techniques provided herein and the present description is not intended to be limited to this particular interconnect layout. As will further be appreciated, other portions of the integrated circuit not shown in these cross-sections can vary from one embodiment to the next. For instance, there may be a device layer below (or above, as the case may be) these interconnect layers, the device layer including a plurality of transistor devices, the interconnect layers providing interconnect to one or more of those transistor devices. The interconnect layers may be part of, for instance, a local interconnect structure just above or below a device layer, or part of a relatively deep backend interconnect structure (e.g., any two neighboring layers of metallization layers M1-M9 above a given device layer). In another example case, the interconnect layers may be part of a memory structure (e.g., dynamic random access memory) that includes an array of bit cells (e.g., 1T-1C bit cells), the interconnect layers providing control signals (e.g., wordline and bitline control signals) to one or more of those bitcells.

The dielectric layer 103 may be implemented with any suitable dielectric or insulator materials, such as silicon dioxide, silicon carbide, silicon nitride, silicon oxynitride, silicon oxycarbonitride, organic polymers (e.g., perfluorocyclobutane or polytetrafluoroethylene), fluorosilicate glass, and organosilicates (e.g., silsesquioxane, siloxane, or organosilicate glass). The dielectric material may be low-k (e.g., k<3.9), standard-k, or high-k (e.g., k>7) depending on the desired isolation and capacitance, and may include pores or voids to further reduce its dielectric constant. Although only two recesses are shown, the dielectric layer 103 may include any number of recesses (e.g., holes for vias, or trenches conductive runs). The recesses can be formed in the dielectric layer, for example, using lithography including via and/or trench patterning and subsequent etch processes (e.g., wet and/or dry etch techniques) followed by planarization, polishing, cleans, or other desired processing. The recess dimensions can vary from one example embodiment to the next. In some example cases, the recess has an opening that is in the range of about 5 nanometers (nm) to 50 nm (e.g., 10 to 25 nm) and a depth in the range of about 5 nm to 500 nm (e.g., 25 to 250 nm), and the recess has an aspect ratio (D2:D1) in the range of about 1:1 to 20:1 (e.g., 5:1). In a more general sense, the recess can any recess including those in which it is difficult to obtain sufficient fill.

The liner 105 can be, for example, a thin conformal film that is conformally deposited (e.g., via ALD, CVD, or other conformal deposition process) on the sidewalls of the recesses to be filled. Any excess liner material (such as that on the field above the recesses) can be removed along with any excess fill material, for instance, using a chemical mechanical planarization (CMP) process. The thickness of the liner 105 can vary from one embodiment to the next, but in some cases is in the range of one to several monolayers to 40 angstroms, such as 5-30 angstroms. The liner 105 is configured to resonate at the microwave frequency range and thus absorbs microwave energy to selectively anneal (heat) the fill material 107a-b to improve gap fill and densification (as shown with 107a in FIG. 1a) and/or modify its grain size (as shown with 107b in FIG. 1b). Some examples of materials that resonate at microwave frequencies (e.g., 2.4-2.5 GHz) or otherwise absorb microwave energy and can be used for liner 105 include inorganic thin films such indium and zinc based oxides (e.g., indium tin oxide; indium gallium zinc oxide; indium tungsten oxide; or zinc oxide), and organic thin films like diethylene glycol dibenzoate (DEGDB). As previously explained above, example materials that do not resonate at microwave frequencies include, for instance, silicon, silicon dioxide, titanium, titanium nitride, tantalum, and tantalum nitride. Such materials have no source to absorb microwave energy and thus do not heat-up when exposed to the microwave-based anneal.

Liner 105 heats material with which it is in contact, including the fill material 107a-b. The amount of heat imparted by liner 105 into its neighboring layer(s) will depend on factors such as the surface area of the contact as well as the material being heated and the volume of that material. So, for instance, consider the example case where liner 105 is deposited on the walls of a high aspect ratio recess (e.g., trench or via having a height-to-width ratio of 4:1 or higher (e.g., 5:1, 6:1, 7:1, etc.) in a relatively large volume of dielectric material 103 (e.g., silicon dioxide), and fill material 107a-b is a metal (and possibly with a relatively thin metal-containing barrier layer between liner 105 and metal fill material 107a-b). For such metal and metal-containing materials, the heat conduction is relatively high and hence liner 105 readily heats the volume of metal fill material 107a-b (and any metal-containing barrier layer, if present). Example fill conductive fill materials 107a-b include, for instance, copper, aluminum, tungsten, molybdenum, ruthenium, or alloys of same, which can be deposited for example by CVD, ALD, electroplating, or other suitable fill material deposition process. Example barrier materials include tantalum, titanium or nitrides of same (e.g., titanium nitride, tantalum nitride, titanium silicon nitride, tantalum silicon nitride), which can be deposited for example by ALD, CVD, or other conformal deposition process. Note that the relative thinness (e.g., 5-30 angstroms) of a given barrier layer allows the heat from the liner to thermally conduct through the barrier layer and into the fill material 107a-b. The thermal conduction for the large volume of dielectric 103 on which liner 105 sits is relatively poor, so that dielectric material 103 will not be sufficiently heated so as to reflow or otherwise materially change in its structure.

In the examples shown in FIGS. 1a-b, the fill material 107a-b is a metal. However, as previously explained above, the fill material 107a-b can be a conductive material (e.g., metal or alloy) or a dielectric material. In the latter case, the techniques allow for better gap fill and densification of the dielectric material. For instance, consider the example case where liner 105 is deposited on the walls of a high aspect ratio recess that is similar to that above but in a relatively large volume of a metal-containing material (in place of dielectric 103), and the relatively smaller volume of fill material 107a-b is a dielectric (and possibly with a metal-containing barrier layer between the liner and the dielectric fill material). Even though the heat conduction in dielectric fill material is relatively poor, the heat generated by liner 105 may be sufficient to heat the smaller volume of dielectric fill material 107a-b within the high aspect ratio recesses so as to achieve at least some reflow in that dielectric material. To this end, liner 105 can be used to heat dielectric material in high aspect ratio narrow openings to achieve better gap fill, according to some examples. Example dielectrics that can be used for fill material 107a-b include, for instance, silicon dioxide, or low-k variants such as silicon dioxide doped with carbon, hydrogen, nitrogen, or fluorine.

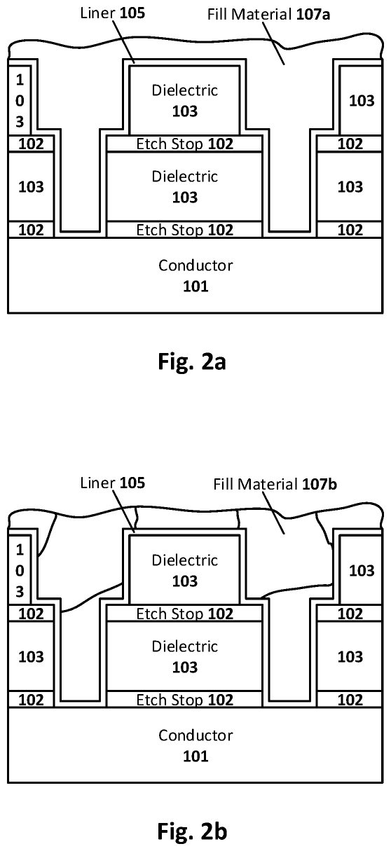

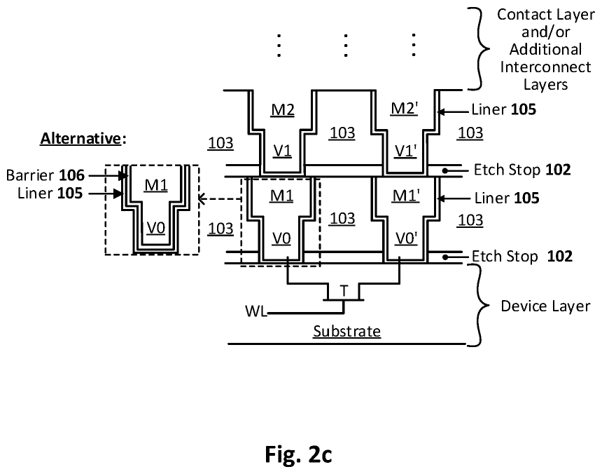

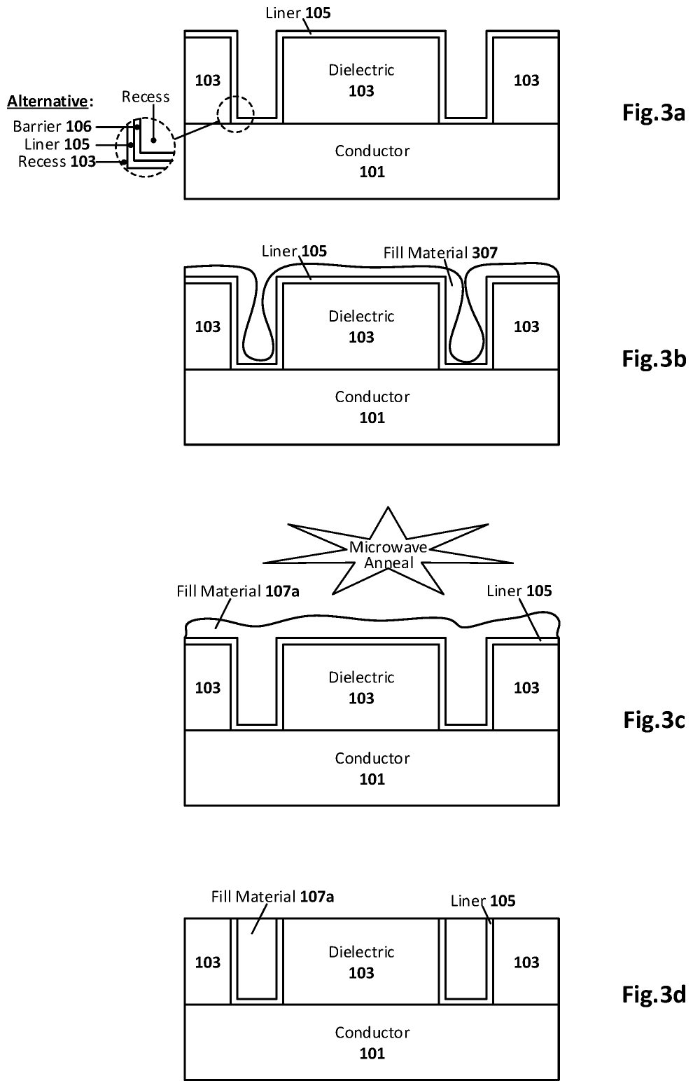

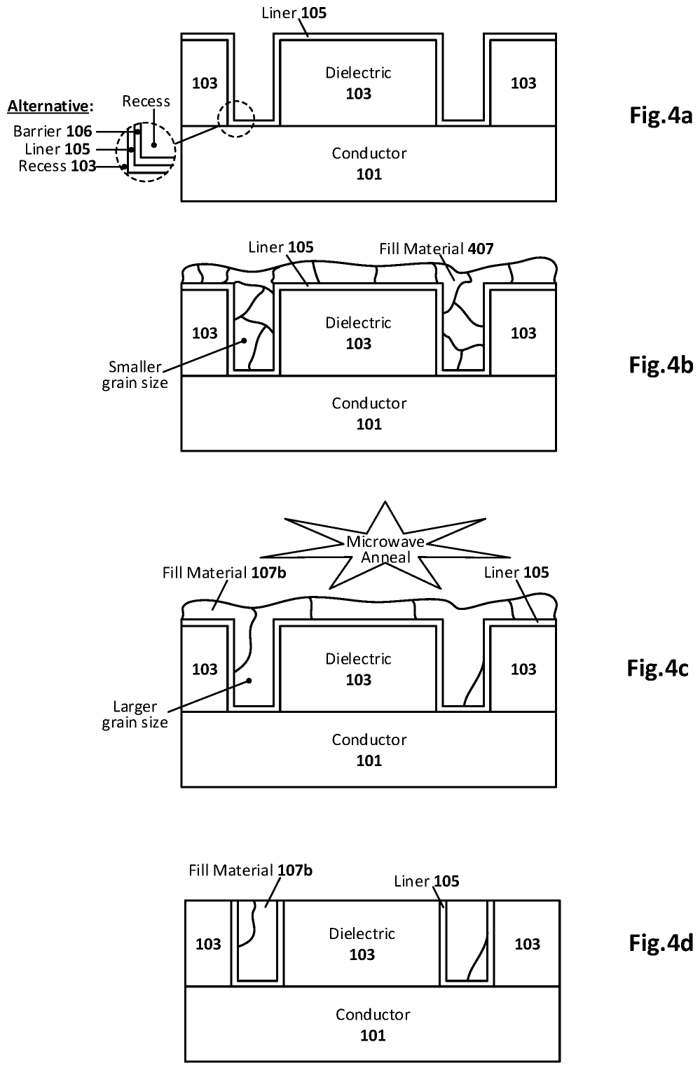

FIGS. 2a-b each illustrates a cross-section view of another example interconnect structure of an integrated circuit configured with a liner that allows for selective annealing of interconnect fill material, in accordance with an embodiment of the present disclosure. As can be seen, these examples are similar to the examples of FIGS. 1a-b, except that these examples have a dual-damascene configuration and etch stop layers between layers of the interconnect structure. The previous relevant discussion is equally applicable here. As can be further seen, this example structure includes three interconnect layers: a lower layer, a middle layer, and an upper layer. The lower layer includes a conductor 101 that extends under each of the dual-damascene recesses. Note that dielectric material of that lower layer is not visible in this particular cross-section. The middle layer includes relatively narrow recesses that are fabricated in a dielectric layer 103. The recesses of this middle layer are holes used for vias of the dual damascene-structure. The upper layer includes relatively wider recesses that are fabricated in another dielectric layer 103. The recesses of this upper layer are trenches used for conductive lines of the dual-damascene structure. Liner 105 is conformal to the sides and bottom of each dual-damascene recess, and a fill material 107a or 107b fills the remaining portion of the recesses. Just as with the example of FIGS. 1a-b, excess liner 105 and fill materials 107a-b have not yet been removed by, for example, way of CMP operations (FIGS. 3d and 4d show example structures after such excess materials have been removed).

In some example cases, the trench opening in the upper layer is about 10 nm to 100 nm (e.g., 20 to 50 nm), and the via opening in the middle layer is about 5 nm to 50 nm (e.g., 10 to 25 nm), and the entire dual-damascene structure has an average height-to-width aspect ratio in the range of about 30:1 to 5:1 (e.g., 10:1). Note that an average width of the dual-damascene structure can be calculated by taking a first width at the mid-portion of the trench in the upper layer, and a second width at the mid-portion of the via in the middle layer, and taking the average of those two widths. The average width can then be used along with the overall height of the dual-damascene structure, to determine the average height-to-width aspect ratio of that trench. As will be appreciated, the geometry and configuration of the dual-damascene structure can vary from one embodiment to the next, and the present description is not intended to be limited to any particular configuration.

Etch stop layers 102 can be, for example, silicon nitride or silicon oxynitride or silicon carbide, or any other material that provides etch selectivity with respect to layer 103. In one example case, etch stop layers 102 include a nitride (e.g., silicon nitride) and layer 103 includes an oxide (e.g., silicon dioxide). Etch stop layers can be provided, for example, by ALD, CVD, or other conformal deposition process.

FIG. 2c schematically illustrates a cross-section view of an example integrated circuit having a device layer and an interconnect structure, the interconnect structure configured with a liner that allows for selective annealing of interconnect fill material, in accordance with still other embodiments of the present disclosure. As can be seen, the example of FIG. 2c is similar to the examples of FIGS. 2a-b, except that this example includes stacked dual-damascene structures (each with a trench/via configuration) and an underlying device layer. Such a configuration can be, for example, part of a memory circuit such as a dynamic random access memory (DRAM) structure of a processor or stand-alone memory chip. In addition, FIG. 2c shows an alternative example embodiment that includes a barrier layer 106 between liner 105 and the fill material making up the trench/via structures (e.g., M1/V0). The previous relevant discussion is equally applicable here.

As can be further seen, a substrate of the device layer is configured with various DRAM cell components integrated therein, such as access transistor T and word line WL. Such DRAM devices may include a plurality of bit cells, with each cell generally including a storage capacitor communicatively coupled to a bitline by way of an access transistor that is gated by a word line. Other standard or proprietary DRAM components and features may also be included (e.g., row and column select circuitry, sense circuitry, power select circuitry, etc.). Each layer includes various metal lines (M1, M1′, M2, and M2′) and corresponding vias (V0, V0′, V1, and V1′) formed within respective dielectric layers 103. Each layer 103 in this example structure is generally isolated or otherwise demarcated from neighboring layers by an etch stop layer 102. In addition, each metal line and via of this example embodiment is configured with a liner 105, as previously discussed. And as further noted, other embodiments may include barrier layer 106 between liner 105 and the fill material making up the trench/via structures. The trench/via structures correspond to fill materials 107a-b.

Any number of suitable substrates can be used to implement the substrate, including bulk substrates (e.g., silicon, germanium, III-V materials, etc.), semiconductor-on-insulator substrates (XOI, where X is a semiconductor material such as silicon, germanium or germanium-enriched silicon), and multi-layered structures such as those suitable for forming nanowire and nanoribbon channel regions. In one specific example case, the substrate is a silicon bulk substrate. In other implementations, the substrate may be formed using alternate materials, which may or may not be combined with silicon, that include but are not limited to germanium, silicon germanium, indium antimonide, lead telluride, indium arsenide, indium phosphide, gallium arsenide, or gallium antimonide. Further materials classified as group III-V or group IV materials may also be used to form the substrate. Although a few examples of materials from which the substrate may be formed are described here, any material that may serve as a foundation upon which an integrated circuit having interconnects and/or conductive features configured with a microwave-resonant liner as variously described herein may be used.

### Methodology

FIGS. 3a-d collectively illustrate cross-section views that demonstrate a methodology for selective annealing to provide better gap fill of interconnect fill material, in accordance with an embodiment of the present disclosure. Note that although the methodology is depicted with cross-sections similar to those showed in FIG. 1a, a similar methodology can be used to form any number of other integrated circuit structures having a microwave-resonant liner configured to selectively heat high aspect ratio fill materials, such as those example structures shown in FIG. 1b and 2a-c and numerous others. The previous relevant discussion (e.g., with respect to materials and dimensions) is equally applicable here.

FIG. 3a shows the resulting structure after a first (upper) interconnect layer is formed over a second (lower) interconnect layer. The lower layer includes a conductor 101 that extends under each of the recesses. Note that dielectric material of the lower layer is not visible in this particular cross-section. As can be seen, the upper interconnect layer includes dielectric 103 and has been patterned and etched to form recesses. As previously explained, the aspect ratio of the recesses an be 1:1, 2:1, 3:1, . . . 5:1, . . . , 10:1, or higher, and the techniques provided herein are particularly useful for filling relatively high aspect ratio features. As can be further seen, microwave-resonant liner 105 has been conformally deposited in the recesses (e.g., by ALD or CVD). In some embodiments, liner 105 includes: (1) oxygen along with indium and/or zinc, or (2) diethylene glycol dibenzoate (DEGDB). The thickness of liner 105 can vary from one embodiment to the next, but in some example cases is in the range of one or so monolayers to 40 angstroms, such as 5-30 angstroms. As can be further seen, there may be a barrier layer 106 conformally deposited on liner 105 (e.g., by ALD or CVD). In some embodiments, barrier layer 106 is amorphous or nanocrystalline and includes refractory-like materials such as: titanium, titanium nitride, titanium silicon nitride, tantalum, tantalum nitride, tantalum silicon nitride. The thickness of barrier layer 106 can vary from one embodiment to the next, but in some example cases is similar to that of liner 105 and is in the range of one or so monolayers to 40 angstroms, such as 5-30 angstroms.

FIG. 3b shows the resulting structure after fill material 307 has been deposited into the recesses (e.g., by ALD, CVD, electroplating) on top of liner 105 (or barrier 106, if present). In this example case, note how a degree of pinch-off has occurred such that the opening of the recesses is closed off (or close to being closed off) and there is still a substantial void in the lower portion of the recess. This is an example of poor fill. Material 307 can be conductive material (e.g., copper, aluminum, tungsten, molybdenum, ruthenium, or alloys of same) or dielectric material (e.g., silicon dioxide). Further note that material 307 is amorphous or nanocrystalline, in this example.

FIG. 3c shows the resulting structure after a microwave-based anneal has been performed to reflow the originally deposited material 307, thereby providing fill material 107a. Note that after such initial microwave-based reflow, more fill material 307 can be deposited into the remaining portion of the recesses, and the microwave-based anneal can be repeated. Such deposition-anneal cycles can be repeated a number of times until the desired gap fill is achieved. Note how the pinched-off voids are gone. In some embodiments, the range of microwave energy used during the anneal process is in the range of 2.4-2.5 Gigahertz (e.g., 2.45 GHz). The duration of the anneal can vary from one embodiment to the next, and depends on factors such as the volume to be heated and the thickness of the liner. The greater the volume and/or the thicker the liner, the longer the anneal may be. An example duration is in the range of several seconds to several minutes, although some examples may call for an even longer duration. In one such example case where the recesses are about 10 to 20 nm wide and 50 to 100 nm deep, and the fill material 307 is copper and the liner and barrier layers are each about 20 to 30 angstroms thick, the duration for each anneal cycle during a given fill process is about 30 to 60 seconds, at 2.4-2.5 Gigahertz (e.g., 2.45 GHz).

FIG. 3d shows the resulting structure after excess liner 105 material (and any excess barrier 106 material, and/or any other excess materials, if present) has been removed, via a planarization or polishing process (e.g., CMP). A next interconnect layer or contact layer or memory cell layer can then be formed on that planarized layer. An etch stop can be used to separate such layers.

FIGS. 4a-c collectively illustrate cross-section views that demonstrate a methodology for selective annealing to provide increased grain size in interconnect fill material, in accordance with an embodiment of the present disclosure. Note that although the methodology is depicted with cross-sections similar to those showed in FIG. 1b, a similar methodology can be used to form any number of other integrated circuit structures having a microwave-resonant liner configured to selectively heat high aspect ratio fill materials, such as those example structures shown in FIGS. 1a and 2a-c and numerous others. The previous relevant discussion (e.g., such as that with respect to materials, dimensions, and use of a barrier layer for materials susceptible to electromigration) is equally applicable here.

FIG. 4a shows the resulting structure after a first (upper) interconnect layer is formed over a second (lower) interconnect layer. The previous relevant discussion with respect to FIG. 3a is equally applicable here.

FIG. 4b shows the resulting structure after fill material 407 has been deposited into the recesses (e.g., by ALD, CVD, electroplating) on top of liner 105 (or barrier 106, if present). In this example case, note that the gap fill is relatively good but the grain size is relatively small. Such smaller grain sizes can provide adequate fill at relatively low temperatures but also may provide relatively high resistance due to, for example, electron scattering caused by grain boundaries. In particular, the smaller the grains, the greater the amount of grain boundary within the fill volume, and thus the greater the amount of electron scattering. Just as with material 307, material 407 can be conductive material (e.g., copper, aluminum, tungsten, molybdenum, ruthenium, or alloys of same) or dielectric material (e.g., silicon dioxide or lower-k doped versions of same).

FIG. 4c shows the resulting structure after a microwave-based anneal has been performed to increase the grain size of the originally deposited material 407, thereby providing material 107b. The previous discussion of FIG. 3c with respect to the frequency range and duration of the microwave-based anneal is equally applicable here. According to some such example embodiments, the pre-anneal smaller grain size on average is in the range of about 20 to 40 angstroms, and the post-anneal larger grain size on average is in the range of about 50 to 100 angstroms.

FIG. 4d shows the resulting structure after excess liner 105 material (and any excess barrier 106 material, and/or any other excess materials, if present) has been removed, via a planarization or polishing process (e.g., CMP). A next interconnect layer or contact layer or memory cell layer can then be formed on that planarized layer. An etch stop can be used to separate such layers.

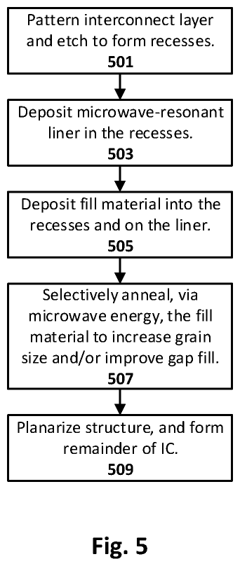

FIG. 5 illustrates a methodology for selective microwave-based annealing of interconnect fill material, in accordance with an embodiment of the present disclosure. The methodology can be used to form any number of integrated circuit structures, including the examples shown in FIGS. 1-4d. As can be seen, the method includes patterning 501 an interconnect layer and etching to form one or more recesses within that layer. Standard or proprietary lithography and etch processing can be used. As previously explained herein, the material being etched to form the one or more recesses therein may be dielectric material or conductive material, and the fill material to be deposited into the recesses and annealed can be conductive material or dielectric material. In any such cases, the techniques provided herein can be used to improve gap fill and/or increase grain size of fill material within a relatively high aspect ratio recess.

The method continues with depositing 503 a microwave-resonant liner into the one or more recesses. Conformal deposition processes such as ALD and/or CVD processes can be used to deposit the liner. The previous discussion with respect to liner materials and geometry is equally applicable here. The method continues with depositing 505 fill material into the trenches and on the liner. In some cases, the method includes depositing a barrier layer on the liner, prior to depositing the fill material. The previous discussion with respect to fill and barrier materials and geometry is equally applicable here. The method continues with selectively annealing 507, via microwave energy, the fill material to increase grain size (e.g., FIGS. 4a-d) and/or improve gap fill (FIGS. 3a-d). The previous discussion with respect to the frequency range and duration of the microwave-based anneal is equally applicable here. The method then continues with planarizing 509 the structure, and forming the remainder of integrated circuit (IC), which may include forming one or more additional interconnect layers that also include a microwave-resonant liner.

### Computing System

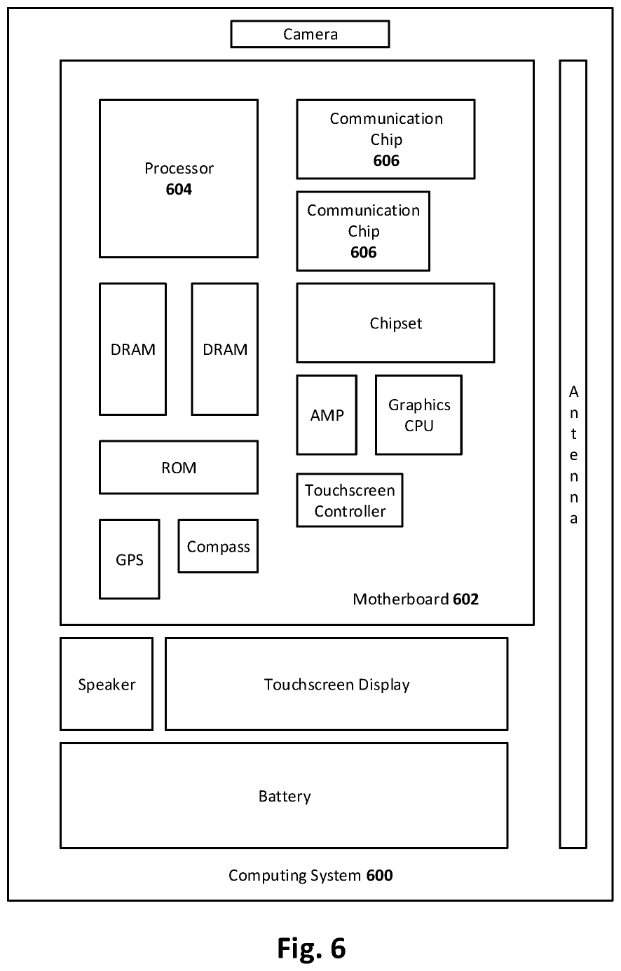

FIG. 6 illustrates a computing system implemented with one or more integrated circuit structures configured in accordance with an embodiment of the present disclosure. As can be seen, the computing system 600 houses a motherboard 602. The motherboard 602 may include a number of components, including but not limited to a processor 604 and at least one communication chip 606 (two are shown in this example), each of which can be physically and electrically coupled to the motherboard 602, or otherwise integrated therein. As will be appreciated, the motherboard 602 may be, for example, any printed circuit board, whether a main board or a daughterboard mounted on a main board or the only board of system 600, etc. Depending on its applications, computing system 600 may include one or more other components that may or may not be physically and electrically coupled to the motherboard 602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 600 may include one or more integrated circuits configured with a microwave-resonant liner, as variously described herein. In some embodiments, multiple functions can be integrated into one or more chips (e.g., for instance, note that the communication chip 606 can be part of or otherwise integrated into the processor 604).

The communication chip 606 enables wireless communications for the transfer of data to and from the computing system 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others. The processor 604 of the computing system 600 includes an integrated circuit die packaged within the processor 604. In some example embodiments of the present disclosure, the integrated circuit die of the processor 604 includes one or more occurrences of a microwave-resonant liner as variously provided herein. The term “processor” may refer to any device or portion of a device that processes, for instance, electronic data from registers and/or memory to transform that electronic data into other electronic data that may be stored in registers and/or memory.

The communication chip 606 may also include an integrated circuit die packaged within the communication chip 606. In accordance with some such example embodiments, the integrated circuit die of the communication chip 606 includes one or more occurrences of a microwave-resonant liner as variously provided herein. As will be appreciated in light of this disclosure, note that multi-standard wireless capability may be integrated directly into the processor 604 (e.g., where functionality of any chips 606 is integrated into processor 604, rather than having separate communication chips). Further note that processor 604 may be a chip set having such wireless capability. In short, any number of processor 604 and/or communication chips 606 can be used. Likewise, any one chip or chip set can have multiple functions integrated therein.

In various implementations, the computing system 600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the system 600 may be any other electronic device that processes data or employs interconnect structures configured with microwave-resonant liners as variously provided herein. As will be appreciated in light of this disclosure, various embodiments of the present disclosure can be used to improve performance on products fabricated at any process node (e.g., in the micron range, or sub-micron and beyond).

### Further Example Embodiments

The following examples pertain to further embodiments, from which numerous permutations and configurations will be apparent.

Example 1 includes an integrated circuit, comprising: a first layer comprising dielectric material, the first layer having a recess that extends into the dielectric material; a second layer within the recess and comprising a metal; and a third layer within the recess and between the first layer and the second layer, the third layer comprising a material that resonates at microwave frequencies.

Example 2 includes the integrated circuit of Example 1, wherein the metal of the second layer is a first metal, and the integrated circuit comprises a fourth layer between the second layer and the third layer, the fourth layer comprising a second metal elementally different from the first metal.

Example 3 includes the integrated circuit of Example 2, wherein: the dielectric material of the first layer comprises silicon and oxygen; the first metal of the second layer comprises copper; the material of the third layer comprises either (1) oxygen along with indium and/or zinc, or (2) diethylene glycol dibenzoate (DEGDB); and the second metal of the fourth layer comprises titanium or tantalum.

Example 4 includes the integrated circuit of Example 3, wherein the material of the third layer comprises: indium, tin, and oxygen; indium, gallium, zinc, and oxygen; indium, tungsten, and oxygen; or zinc and oxygen.

Example 5 includes the integrated circuit of Example 3, wherein the material of the third layer comprises diethylene glycol dibenzoate (DEGDB).

Example 6 includes the integrated circuit of any one of Examples 1 through 5, wherein the metal of the second layer comprises at least one of copper, aluminum, tungsten, molybdenum, or ruthenium.

Example 7 includes the integrated circuit of any one of Examples 1 through 6, wherein the dielectric material of the first layer comprises silicon and oxygen.

Example 8 includes the integrated circuit of any one of Examples 1 through 7, wherein the dielectric material of the first layer includes at least one of carbon, hydrogen, nitrogen, or fluorine.

Example 9 includes the integrated circuit of any one of Examples 1 through 8, wherein the material of the third layer resonates at frequencies in the range of 2.4 gigahertz to 2.5 gigahertz.

Example 10 includes the integrated circuit of any one of Examples 1 through 9, wherein the third layer has a thickness in the range of 5 angstroms to 30 angstroms.

Example 11 includes the integrated circuit of any one of Examples 1 through 10, wherein the recess is a dual damascene recess.

Example 12 includes the integrated circuit of any one of Examples 1 through 11, and further includes a plurality of transistor devices above or below the first layer, wherein at least one of the transistor devices is connected to the second layer.

Example 13 includes the integrated circuit of any one of Examples 1 through 12, wherein the material of the third layer comprises: oxygen along with indium and/or zinc; or diethylene glycol dibenzoate (DEGDB).

Example 14 includes the integrated circuit of Example 13, wherein the material of the third layer comprises: indium, tin, and oxygen; indium, gallium, zinc, and oxygen; indium, tungsten, and oxygen; or zinc and oxygen.

Example 15 includes the integrated circuit of Example 13, wherein the material of the third layer comprises diethylene glycol dibenzoate (DEGDB).

Example 16 is an electronic system comprising the integrated circuit of any one of Examples 1 through 15. The electronic system may be, for instance, a general-purpose computer (e.g., laptop or desktop) or mobile communication device (e.g., smartphone) or a special-purpose computer (e.g., game console or measurement system).

Example 17 is microprocessor or memory chip comprising the integrated circuit of any one of Examples 1 through 15.

Example 18 is an integrated circuit, comprising: a first layer comprising dielectric material, the first layer having a recess that extends into the dielectric material, the dielectric material including silicon and oxygen; a second layer within the recess and comprising copper or aluminum; a third layer within the recess and between the first layer and the second layer, the third layer comprising a material that resonates at microwave frequencies; and a fourth layer between the second layer and the third layer, the fourth layer comprising at least one of titanium or tantalum.

Example 19 includes the integrated circuit of Example 18, wherein the recess is a dual damascene recess.

Example 20 includes the integrated circuit of Example 18 or 19, wherein the material of the third layer comprises: indium, tin, and oxygen; indium, gallium, zinc, and oxygen; indium, tungsten, and oxygen; or zinc and oxygen.

Example 21 includes the integrated circuit of Example 18 or 19, wherein the material of the third layer comprises diethylene glycol dibenzoate (DEGDB).

Example 22 is an integrated circuit, comprising: a first layer comprising dielectric material, the first layer having a recess that extends into the dielectric material; a second layer within the recess and comprising a metal; and a third layer within the recess and between the first layer and the second layer, the third layer including (1) oxygen along with indium and/or zinc, or (2) diethylene glycol dibenzoate (DEGDB).

Example 23 includes the integrated circuit of Example 22, wherein the metal of the second layer is a first metal, and the integrated circuit comprises a fourth layer between the second layer and the third layer, the fourth layer comprising a second metal elementally different from the first metal.

Example 24 includes the integrated circuit of Example 23, wherein the dielectric material of the first layer comprises silicon and oxygen; the first metal of the second layer comprises copper; and the second metal of the fourth layer comprises titanium or tantalum.

Example 25 includes the integrated circuit of any one of Examples 22 through 24, wherein the metal of the second layer comprises at least one of copper, aluminum, tungsten, molybdenum, or ruthenium.

Example 26 includes the integrated circuit of any one of Examples 22 through 25, wherein the dielectric material of the first layer comprises silicon and oxygen.

Example 27 includes the integrated circuit of any one of Examples 22 through 26, wherein the dielectric material of the first layer includes at least one of carbon, hydrogen, nitrogen, or fluorine.

Example 28 includes the integrated circuit of any one of Examples 22 through 27, wherein the material of the third layer comprises: indium, tin, and oxygen; indium, gallium, zinc, and oxygen; indium, tungsten, and oxygen; or zinc and oxygen.

Example 29 includes the integrated circuit of any one of Examples 22 through 27, wherein the material of the third layer comprises diethylene glycol dibenzoate (DEGDB).

Example 30 is an integrated circuit, comprising: a first layer having a recess that extends into the first layer; a second layer within the recess and comprising a metal or a dielectric; and a third layer within the recess and between the first layer and the second layer, the third layer including (1) oxygen along with indium and/or zinc, or (2) diethylene glycol dibenzoate (DEGDB).

Example 31 includes the integrated circuit of Example 30, and further includes a fourth layer between the second layer and the third layer.

Example 32 includes the integrated circuit of Example 30, wherein the first layer comprises silicon and oxygen; the second layer comprises copper; and the fourth layer comprises titanium or tantalum.

Example 33 includes the integrated circuit of any one of Examples 30 through 32, wherein the second layer comprises at least one of copper, aluminum, tungsten, molybdenum, or ruthenium.

Example 34 includes the integrated circuit of any one of Examples 30 through 33, wherein the first layer comprises silicon and oxygen.

Example 35 includes the integrated circuit of any one of Examples 30 through 34, wherein the first layer includes at least one of carbon, hydrogen, nitrogen, or fluorine.

Example 36 includes the integrated circuit of any one of Examples 30 through 35, wherein the third layer comprises: indium, tin, and oxygen; indium, gallium, zinc, and oxygen; indium, tungsten, and oxygen; or zinc and oxygen.

Example 37 includes the integrated circuit of any one of Examples 30 through 35, wherein the third layer comprises diethylene glycol dibenzoate (DEGDB).

Example 38 is a method for forming an integrated circuit, the method comprising: forming a first layer having a recess that extends into the first layer; forming a second layer within the recess, the second layer including (1) oxygen along with indium and/or zinc, or (2) diethylene glycol dibenzoate (DEGDB); and forming, after forming the second layer, a third layer within the recess and comprising a metal or a dielectric.

Example 39 includes the method of Example 38, wherein forming the first layer includes patterning an interconnect layer and etching to form one or more trenches within the interconnect layer, the recess being one of the one or more trenches.

Example 40 includes the method of Example 38 or 39, wherein forming the second layer includes conformally depositing the second layer in the one or more trenches, prior to forming the third layer.

Example 41 includes the method of Example 40, wherein forming the third layer includes: depositing fill material into the one or more trenches, the fill material being one of the metal or the dielectric of the third layer; and selectively annealing, via microwave energy, the fill material to increase grain size and/or improve gap fill.

Example 42 includes the method of Example 41, wherein selectively annealing, via microwave energy, the fill material to increase grain size and/or improve gap fill is performed for a period in the range of 3 seconds to 30 minutes.

Example 43 includes the method of Example 41 or 42, wherein selectively annealing, via microwave energy, the fill material to increase grain size and/or improve gap fill is performed at a frequency in the range of 2.4 gigahertz to 2.5 gigahertz.

Example 44 includes the method of any one of Examples 38 through 43, wherein after forming the second layer and before forming the third layer, the method includes forming a fourth layer within the recess.

Example 45 includes the method of Example 44, wherein the first layer comprises silicon and oxygen; the third layer comprises copper; and the fourth layer comprises titanium or tantalum.

Example 46 includes the method of any one of Examples 38 through 45, wherein the third layer comprises at least one of copper, aluminum, tungsten, molybdenum, or ruthenium.

Example 47 includes the method of any one of Examples 38 through 46, wherein the first layer comprises silicon and oxygen.

Example 48 includes the method of any one of Examples 38 through 47, wherein the first layer includes at least one of carbon, hydrogen, nitrogen, or fluorine.

Example 49 includes the method of any one of Examples 38 through 48, wherein the second layer comprises: indium, tin, and oxygen; indium, gallium, zinc, and oxygen; indium, tungsten, and oxygen; or zinc and oxygen.

Example 50 includes the method of any one of Examples 38 through 48, wherein the second layer comprises diethylene glycol dibenzoate (DEGDB).

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit, comprising:
a first layer comprising dielectric material, the first layer having a recess that extends into the dielectric material;
a second layer within the recess and comprising a metal; and
a third layer within the recess and between the first layer and the second layer, the third layer comprising a material that resonates at microwave frequencies.

2. The integrated circuit of claim 1, wherein the metal of the second layer is a first metal, and the integrated circuit comprises a fourth layer between the second layer and the third layer, the fourth layer comprising a second metal elementally different from the first metal.

3. The integrated circuit of claim 2, wherein:
the dielectric material of the first layer comprises silicon and oxygen;
the first metal of the second layer comprises copper;
the material of the third layer comprises either (1) oxygen along with indium and/or zinc, or (2) diethylene glycol dibenzoate (DEGDB); and
the second metal of the fourth layer comprises titanium or tantalum.

4. The integrated circuit of claim 3, wherein the material of the third layer comprises:
indium, tin, and oxygen; indium, gallium, zinc, and oxygen; indium, tungsten, and oxygen; or zinc and oxygen.

5. The integrated circuit of claim 3, wherein the material of the third layer comprises diethylene glycol dibenzoate (DEGDB).

6. The integrated circuit of claim 1, wherein the metal of the second layer comprises at least one of copper, aluminum, tungsten, molybdenum, or ruthenium.

7. The integrated circuit of claim 1, wherein the dielectric material of the first layer comprises silicon and oxygen.

8. The integrated circuit of claim 7, wherein the dielectric material of the first layer includes at least one of carbon, hydrogen, nitrogen, or fluorine.

9. The integrated circuit of claim 1, wherein the material of the third layer resonates at frequencies in the range of 2.4 gigahertz to 2.5 gigahertz.

10. The integrated circuit of claim 1, wherein the third layer has a thickness in the range of 5 angstroms to 30 angstroms.

11. The integrated circuit of claim 1, wherein the recess is a dual damascene recess.

12. The integrated circuit of claim 1, comprising a plurality of transistor devices above or below the first layer, wherein at least one of the transistor devices is connected to the second layer.

13. The integrated circuit of claim 1, wherein the material of the third layer comprises:
oxygen along with indium and/or zinc; or
diethylene glycol dibenzoate (DEGDB).

14. The integrated circuit of claim 13, wherein the material of the third layer comprises: indium, tin, and oxygen; indium, gallium, zinc, and oxygen; indium, tungsten, and oxygen; or zinc and oxygen.

15. The integrated circuit of claim 13, wherein the material of the third layer comprises diethylene glycol dibenzoate (DEGDB).

16. An integrated circuit, comprising:
a first layer comprising dielectric material, the first layer having a recess that extends into the dielectric material, the dielectric material including silicon and oxygen;
a second layer within the recess and comprising copper or aluminum;
a third layer within the recess and between the first layer and the second layer, the third layer comprising a material that resonates at microwave frequencies; and
a fourth layer between the second layer and the third layer, the fourth layer comprising at least one of titanium or tantalum.

17. The integrated circuit of claim 16, wherein the material of the third layer comprises: indium, tin, and oxygen; indium, gallium, zinc, and oxygen; indium, tungsten, and oxygen; zinc and oxygen; or diethylene glycol dibenzoate (DEGDB).

18. An integrated circuit, comprising:
a first layer having a recess that extends into the first layer;
a second layer within the recess and comprising a metal or a dielectric; and
a third layer within the recess and between the first layer and the second layer, the third layer including
(1) oxygen along with indium and/or zinc, or
(2) diethylene glycol dibenzoate (DEGDB).

19. The integrated circuit of claim 18, comprising a fourth layer between the second layer and the third layer, wherein:
the first layer comprises silicon and oxygen;
the second layer comprises copper; and
the fourth layer comprises titanium or tantalum.

20. The integrated circuit of claim 18, wherein the third layer comprises: indium, tin, and oxygen; indium, gallium, zinc, and oxygen; indium, tungsten, and oxygen; or zinc and oxygen.
